(19) United States
(12) Patent Application Publication
(10) Pub. No.: US 2024/0072511 A1
(43) Pub. Date: Feb. 29, 2024

(54) Heterogeneous Integration Using a Germanium Handle Substrate

(71) Applicant: Quintessent Inc., Goleta, CA (US)

(72) Inventors: Justin Colby NORMAN, Goleta, CA (US); Brian KOCH, Santa Barbara, CA (US); Alan LIU, Santa Barbara, CA (US)

(21) Appl. No.: 18/232,178

(22) Filed: Aug. 9, 2023

Related U.S. Application Data
(60) Provisional application No. 63/401,233, filed on Aug. 26, 2022.

(51) Int. Cl. H01S 5/02; H01S 5/34

(52) U.S. Cl. CPC H01S 5/0215; H01S 5/021; H01S 5/0217; H01S 5/3412

(57) ABSTRACT

The present Specification is directed to the heterogeneous integration of compound-semiconductor devices on indirect-bandgap material substrates. A chip comprising compound-semiconductor layer stack disposed on a handle substrate of germanium is bonded, stack-side down, to a silicon layer disposed on a host substrate. The use of a germanium handle substrate enables the handle substrate to be removed after bonding using methods that are highly selective for germanium over the compound semiconductor layer stack. As a result, the compound-semiconductor layer stack does not need to be protected during handle substrate removal and the handle substrate can be completely removed without causing damage to the compound-semiconductor layer stack. As a result, after handle-substrate removal, the materials of the layer stack can be processed further to define one or more optically active devices in conventional fashion.

### CROSS REFERENCE TO RELATED APPLICATIONS

This case claims priority of U.S. Provisional Patent Application Ser. No. 63/401,233, filed Aug. 26, 2022 (Attorney Docket: 3218-014PR1), which is incorporated herein by reference. If there are any contradictions or inconsistencies in language between this application and one or more of the cases that have been incorporated by reference that might affect the interpretation of the claims in this case, the claims in this case should be interpreted to be consistent with the language in this case.

### TECHNICAL FIELD

The present disclosure relates to heterogeneous integration of direct-bandgap-semiconductor-based and indirect-bandgap-semiconductor devices and, more specifically, to photonic integrated circuits comprising heterogeneously integrated compound-semiconductor optical devices and silicon-based planar-lightwave circuits.

### BACKGROUND

Heterogeneous integration of lasers, optical amplifiers, and/or other optical components comprising compound-semiconductor materials disposed on indirect-bandgap materials, such as silicon, silicon nitride, and the like, can provide many benefits; however, there are significant manufacturing challenges for producing such systems in volume and/or at low cost.

Historically, the most common approach for realizing such systems relies on separate formation of (1) an appropriate optical-layer stack that is epitaxially grown on a compound-semiconductor substrate and (2) one or more silicon waveguides disposed on a silicon substrate. Chips taken from the compound-semiconductor substrate are then joined, optical-layer-stack-side down to the silicon waveguides using conventional chip-bonding methods.

After bonding, the compound-semiconductor substrate material is removed via one or more processes such as grinding, polishing, wet etching, and/or dry etching, thereby leaving just regions of optical-layer-stack material attached to the silicon substrate. The desired optical devices are then defined from the regions of optical-layer-stack material using conventional processing techniques.

While this approach avoids the need for precise alignment required for bonding fully fabricated optical devices onto silicon waveguides and has been proven to work well even at high volumes, the removal of the compound-semiconductor substrates of the chips can be extremely challenging. Typically, the chips must be relatively thick to withstand the mechanical forces exerted on them during the bonding process. As a result, the amount of substrate material that must be removed from each chip to expose the desired optical layers for further processing can be substantial.

In addition, grinding and polishing processes are time consuming and can be challenging to perform without damaging the optical-layer-stack material. Furthermore, it is difficult, if not impossible, to target an exact final desired thickness using grinding and/or polishing, so additional wet and/or dry etching is nearly always required.

Unfortunately, wet and dry etching processes pose their own challenges to manufacture due to a limited etch selectivity for different layers of the optical-layer stack. When the edges of the III-V chips are exposed, for example, the chemicals used to etch the substrate material can also attack one or more layers of the optical-layer stack by etching inward from the exposed edges. As a result, the edges of each region of optical-layer material may not be useable, wasting valuable optical-layer material, as well as real estate on the silicon substrate.

Transfer printing is an alternative approach to chip-bonding-based heterogeneous integration that can potentially avoid some of the complications outlined above. In transfer printing, chips containing fully fabricated compound-semiconductor optical devices are bonded onto a host substrate containing optical waveguides. Unfortunately, precise alignment between the small waveguide features on the optical-device chips and the optical waveguides on the host substrate can be difficult, if not impossible, to achieve in a volume-manufacturing setting. Furthermore, high-precision alignment equipment is expensive and the alignment process is time consuming, leading to extremely high manufacturing cost. Still further, transfer printing fails to leverage the well-developed technology base associated with wafer-scale manufacturing, process, and quality control tools available in a modern large-diameter (200 mm or greater) integrated-circuit foundry.

A practical and inexpensive wafer-scale approach for adding compound-semiconductor optical material onto a waveguide-containing indirect-bandgap substrate suitable for high-volume, low-cost production would be an important advance in the state of the art of heterogeneous integration.

### SUMMARY

The present disclosure enables heterogeneous integration of compound-semiconductor-based optical devices onto indirect-bandgap-material substrates without some of the cost and disadvantages of the prior art. Embodiments in accordance with the present disclosure are particularly well suited for use in fabricating photonic integrated circuits, heterogeneously integrated lasers, and the like.

An advance over the prior art is realized by employing a germanium substrate as a handle substrate on which optical-device material is disposed. The optical-device material can then be bonded to a silicon substrate in conventional fashion, after which the entire handle substrate can be removed via a simple, highly selective wet etch that does not affect the optical-device material. As a result, the cumbersome operations used in the prior art to remove a compound-semiconductor handle substrate after bonding to an indirect-bandgap-material substrate can be avoided entirely. Furthermore, the yield degradation associated with conventional handle-substrate removal is mitigated. Still further, the percentage of bonded optical-device material that is usable is substantially increased, thereby significantly reducing fabrication cost.

An illustrative embodiment in accordance with the present disclosure is a method for fabricating a heterogeneously integrated light source wherein a germanium substrate containing the constituent layers of a gallium-arsenide laser is bonded to a silicon substrate comprising a silicon waveguide such that the constituent layers are optically coupled with the silicon waveguide. After bonding, the germanium substrate is removed using an etchant that selectively attacks germanium while not significantly affecting the constituent layers of the laser.

Once the germanium substrate is removed, the now substantially planar substrate is fully processed using conventional processing technology to define the light source and vertical couplers that enable propagation of optical energy generated by the light source into the silicon waveguide.

An alternative embodiment is a gallium arsenide edge-emitting laser whose device layers are disposed on a germanium substrate. The device layers are fully processed to define a laser and its electrical contacts. The fully fabricated laser is bonded to a host substrate containing a silicon waveguide and a trench in which electrical traces are formed such that the electrical contacts of the laser are physically and electrically joined with the electrical traces. The trench is configured such that the emitting facet of the laser is vertically aligned with the silicon waveguide, thereby enabling low-loss butt-coupling between them. In some embodiments, the germanium substrate is then removed using a highly selective etch, leaving only the thin layers of materials needed to form the laser. The remaining material can be configured such that it is recessed below the top of the trench or protrudes only slightly above the trench, giving rise to a substantially planarized surface.

In some embodiments, the optical-device material is processed to define an optically active device other than a laser, such as a modulator, an amplifier, a detector, and the like.

An embodiment in accordance with the present disclosure is a method including: providing a compound-semiconductor (CS) chip that includes a first CS layer disposed on a first handle substrate comprising germanium; providing a host substrate including a first layer that comprises a first material that is selected from the group consisting of a dielectric layer and an indirect-bandgap semiconductor; joining the CS chip and the host substrate such that the first CS layer is between the host substrate and the first handle substrate; and removing the first handle substrate.

Another embodiment in accordance with the present disclosure is a method including: providing a compound-semiconductor (CS) chip that includes a plurality of CS layers that collectively define a CS stack, the CS stack being disposed on a first handle substrate consisting of germanium; providing a host substrate that is a silicon-on-insulator substrate including a silicon handle substrate, a buried oxide layer, and a device layer that comprises single-crystal silicon, wherein the device layer is patterned to define a first silicon waveguide; joining the CS chip and the host substrate such that the CS stack is between the silicon handle substrate and the first handle substrate; and removing the first handle substrate.

### BRIEF DESCRIPTION OF THE DRAWINGS

FIGS. 1A-B depict schematic drawings of sectional views of a nascent heterogeneously integrated optical system, before and after removal of the handle substrate of a compound-semiconductor chip bonded on a host substrate, respectively, in accordance with the prior art.

FIGS. 2A-B depict sectional views of a nascent heterogeneously integrated optical system in which the edges of a bonded CS chip have been protected with an edge coating, before and after removal of the handle substrate of a compound-semiconductor chip bonded on a host substrate, respectively, in accordance with the prior art.

FIG. 3 depicts a schematic drawing of a top view of an exemplary integrated-optics system in accordance with the present disclosure.

FIG. 4 depicts operations of a method for forming an integrated-optics system in accordance with the present disclosure.

FIGS. 5A-B depict schematic drawings of cross-sectional views of a host substrate and CS chip, respectively, in accordance with the present disclosure.

FIG. 6A depicts a schematic drawing of nascent system 300′ after CS chip 500 and host substrate 102 are joined in accordance with the illustrative embodiment.

FIG. 6B depicts a schematic drawing of nascent system 300′ after the removal of handle substrate 504.

FIG. 7A depicts a schematic drawing of a cross-sectional view of a portion of a compound-semiconductor chip in accordance with an alternative embodiment comprising a laser that is edge coupled with a silicon waveguide in accordance with the present disclosure.

FIG. 7B depicts a schematic drawing of a cross-sectional view of a nascent integrated-optics system in accordance with the alternative embodiment.

FIG. 7C depicts a schematic drawing of a cross-sectional view of completed system 716.

### DETAILED DESCRIPTION

For the purposes of the present disclosure, including the appended claims, the following terms are defined:
i. “disposed on” or “formed on” is defined as “exists on” an underlying material or layer with or without intermediate layers. For example, if a material is described to be “disposed (or grown) on a substrate,” this can mean that either (1) the material is in intimate contact with the substrate; or (2) the material is in contact with one or more layers that reside on the substrate.
ii. optically active device is defined as an electrically coupled device (i.e., a device comprising electrical contacts for connecting to external circuitry) in which, in response to an electrical signal applied to the electrical contacts, either (a) photons are generated due to the recombination of free carriers or (b) free-carrier pairs are generated due to the absorption of photons and/or (c) an optical index of refraction change occurs. Examples of optically active devices include, without limitation, lasers, optical amplifiers, optical modulators (e.g., electro-absorption modulators, phase modulators, etc.), variable optical attenuators, photodetectors, and the like. It should be noted that an optically active device does not require inclusion of a quantum-element-containing layer.
iii. quantum element is defined as a semiconductor structure that exhibits a quantum effect. Examples of quantum elements include, without limitation, quantum dots, quantum wells, quantum-well layers, quantum dashes, quantum wires, and the like.
iv. passive waveguide is defined as a surface waveguide in which light passes through virtually unperturbed. Passive waveguides are not operatively coupled with electrical contacts and are not stimulated to exhibit optoelectronic effects, such conversion of free carriers into photons or vice versa, optical modulation, optical amplification, and the like.

For the purposes of this Specification, including the appended claims, the terms “lateral” and “vertical” as used are meant to be relative to the major surfaces of a substrate on which an integrated-optics system resides, where the term lateral refers to directions that are parallel to the major surfaces and the term vertical refers to directions that are normal to the major surfaces. In similar fashion, the term “lower” means more proximate to the substrate and the term “higher” means more distal from the substrate.

As noted above, prior-art approaches for the heterogeneous integration of optical-layer material on indirect-bandgap-semiconductor host substrates are fraught with challenges that have, thus far, limited their use in many applications. In particular, removal of the handle-substrate material of a compound-semiconductor (CS) chip comprising optical-layer material after the chip has been bonded to the host substrate is difficult and can give rise to significant additional cost and reliability issues.

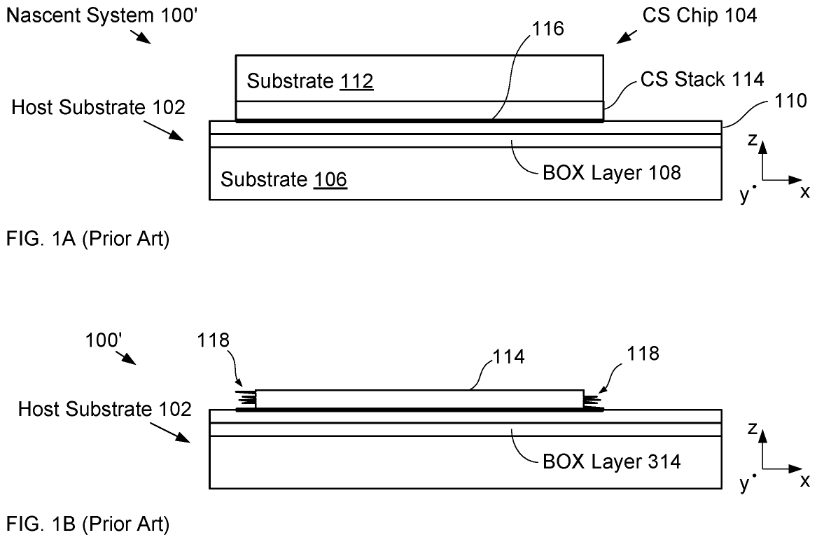

FIGS. 1A-B depict schematic drawings of sectional views of a nascent heterogeneously integrated optical system, before and after removal of the handle substrate of a compound-semiconductor chip bonded on a host substrate, respectively, in accordance with the prior art. Nascent system 100′ includes host substrate 102 and CS chip 104.

Host substrate 102 is a conventional silicon-on-insulator (SOI) substrate that includes handle substrate 106, buried-oxide layer (BOX) 108, and device layer 110. Handle substrate 106 is a conventional silicon wafer and device layer 110 is a layer of single-crystal silicon that is patterned to define a silicon waveguide. In some embodiments, device layer 110 is not patterned to define a silicon waveguide. In some embodiments, device layer 110 is patterned to define more than one silicon waveguide. In some embodiments, device layer 110 is an indirect-bandgap semiconductor other than silicon. In some embodiments, host substrate 102 is a bulk substrate of a material suitable for use in heterogeneous integration with CS chip 104, such as silicon, glass, fused silica, quartz, etc.

CS chip 104 includes handle substrate 112 and CS stack 114.

Handle substrate 112 is a conventional gallium arsenide wafer that functions as a handle substrate for CS stack 114.

CS stack 114 is a layer stack comprising several gallium-arsenide and gallium-arsenide-compound layers suitable for forming an optically active device (e.g., a laser, modulator, etc.). Typically, CS stack 114 and handle substrate 112 are composed of substantially similar compound-semiconductor materials. In the depicted example, these materials include gallium arsenide and related compounds (e.g., aluminum gallium arsenide, indium gallium arsenide phosphide, etc.).

CS chip 104 is bonded to host substrate such that CS stack 114 and device layer 110 are joined at bonding interface 116 via conventional bonding technology (e.g., oxygen-assisted plasma bonding, etc.).

After bonding, the majority of handle substrate 112 is removed by grinding and polishing, typically followed by a wet etch to remove additional substrate material.

Unfortunately, as shown in FIG. 1B, because the edges of CS chip 104 are exposed during substrate removal and its layers are of similar material to that of the substrate being removed, the etchant used to remove substrate material has limited etch selectivity for the substrate material over the materials of CS stack 114. In other words, as the etchant attacks the substrate material during the substrate removal process, the material at the exposed edges of CS stack 114 is also attacked, thereby producing damaged regions 118 around the perimeter of CS stack 114.

As a result, the perimeter of CS stack 114 becomes substantially unusable for forming optical devices. This significantly increases fabrication cost due to the fact that larger CS chips must be used than the area required for the respective optical devices formed from them. In addition, larger CS chips require that additional valuable real estate must be reserved on the host wafer for the finished optical devices.

Prior-art approaches for mitigating edge attack during substrate removal have been pursued, such as protecting the edges of the bonded chips by sealing them with wax, etc. Some examples of such attempts are described by H. Park, et al., in “Photonic Integration on the Hybrid Silicon Evanescent Device Platform,” Advances in Optical Technologies, Vol. 2008, Article ID 682978 (2008), doi.org/10.1155/2008/682978, which is incorporated herein by reference.

Unfortunately, edge-sealing approaches typically lead to other issues, such as large topography that can make processing of the optical-layer material difficult, if not impossible.

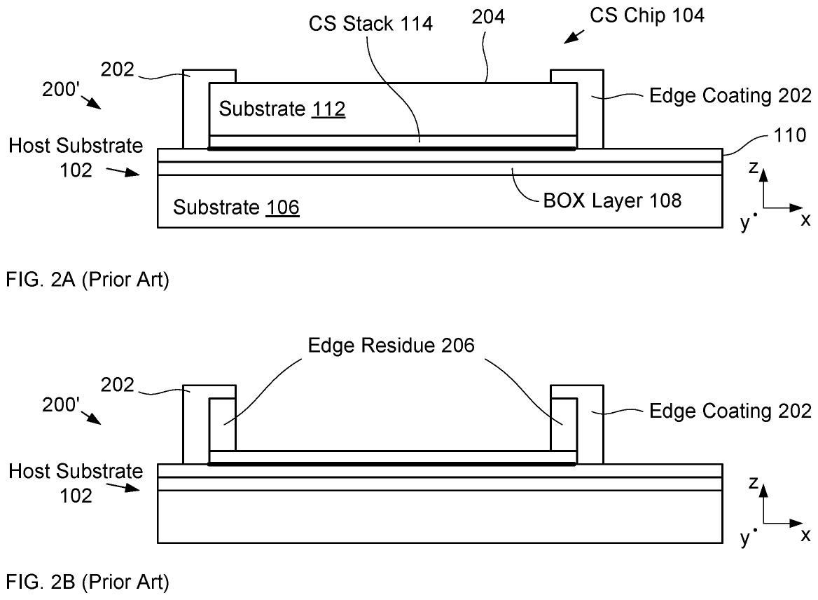

FIGS. 2A-B depict sectional views of a nascent heterogeneously integrated optical system in which the edges of a bonded CS chip have been protected with an edge coating, before and after removal of the handle substrate of a compound-semiconductor chip bonded on a host substrate, respectively, in accordance with the prior art.

In nascent system 200′, edge coating 202 is applied to seal the sidewalls of CS chip 104 to protect them from attack by the chemicals used to thin/remove handle substrate 112. Unfortunately, while edge coating 202 can successfully mitigate damage to the perimeter of CS stack 114 during substrate removal, it adds significant process complexity associated with formation of the edge protection itself, as well as its removal afterward.

In addition, edge coating 202 typically extends onto back surface 204 of handle substrate 112 during its formation. As a result, its presence during substrate removal gives rise to edge residue 206, which can have large topography. To enable further processing of CS stack 114, therefore, both edge coating 202 and edge residue 206 must typically be removed, which adds further processing complexity.

It is an aspect of the present disclosure, however, that many, if not all, of the myriad problems inherent to prior-art approaches to heterogeneous integration of compound-semiconductor-based optical devices onto indirect-bandgap substrates can be mitigated, or avoided completely, by using CS chips whose optical-layer material is disposed on a handle substrate comprising, or consisting of, germanium. The teachings of the present disclosure, therefore, enable simple, low-cost, and highly reliable removal of the handle substrate of a CS chip after the chip is bonded to its host substrate.

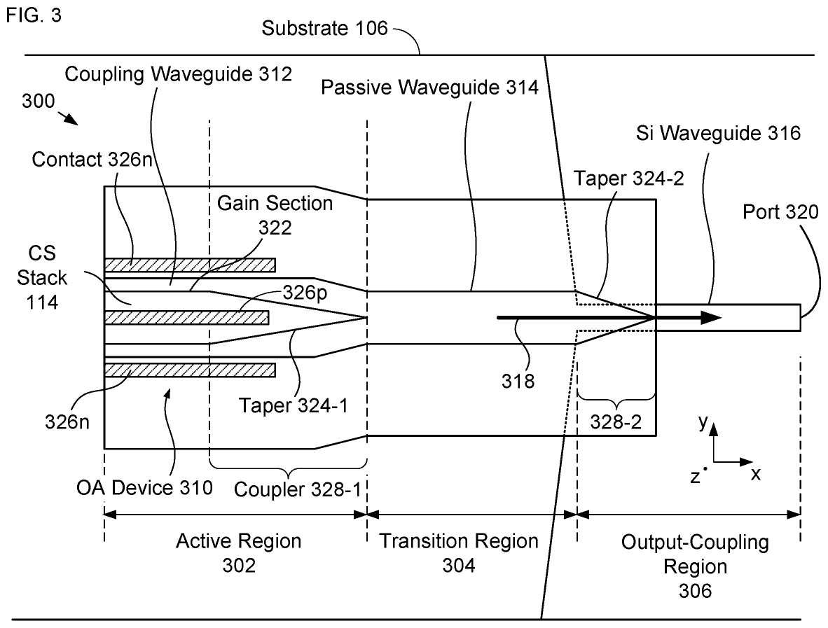

FIG. 3 depicts a schematic drawing of a top view of an exemplary integrated-optics system in accordance with the present disclosure. System 300 includes active region 302, transition region 304, and output-coupling region 306, which are disposed on handle substrate 106, as discussed above.

Active region 302, transition region 304, and output-coupling region 306 are contiguous regions that collectively define an integrated-optics-based, silicon-waveguide-coupled laser, such as those described in detail in U.S. Patent Publication No. US2021/0215874 (now U.S. Pat. No. 11,131,806), published Jul. 15, 2021, which is incorporated herein by reference.

System 300 comprises optically active (OA) device 310, coupling waveguide 312, passive waveguide 314, and silicon waveguide 316, which are arranged such that optical energy generated by OA device 310 propagates as light signal 318 from the laser to port 320.

It should be noted that, although the depicted example is an integrated-optics-based, silicon-waveguide-coupled laser wherein light is generated in an optically active device and propagates to a waveguide port, embodiments in accordance with the present disclosure include systems wherein a light signal is coupled into a waveguide port and conveyed to an OA device. Furthermore, in some embodiments, no silicon waveguide is included and port 320 is located in passive waveguide 314. Furthermore, in some embodiments, more than one passive waveguide and/or silicon waveguide is included. Still further, in some embodiments, the teachings of the present disclosure enable heterogeneous integration of non-optical devices on a silicon-based host substrate.

Active region 302 is defined by the structure of OA device 310. OA device 310 includes CS stack 114, which is patterned to define gain section 322 and taper 324-1. It should be noted that active material is present only in active region 302 and removed from the other regions of system 300, as discussed below.

Transition region 304 is defined by the structure of passive waveguide 314, which is defined by patterning a coupling layer included in CS stack 114, as discussed below.

Output coupling region 306 is defined by the structure of silicon waveguide 316.

In operation, optical energy is generated by gain section 322 in response to an electrical stimulus provided between contact 326p and contacts 326n. The lateral dimensions of OA device 310 substantially determine the vertical position at which optical energy forms an optical mode in the device, as well as the shape of that optical mode. As a result, CS stack 114 is defined such that optical energy generated in gain section 322 forms an optical mode, while taper 324-1 is configured to force that optical mode into coupling waveguide 312. Coupling waveguide 312 is defined from the coupling layer included in CS stack 114, as discussed below. Taper 324-1 and coupling waveguide 312 collectively define vertical coupler 328-1.

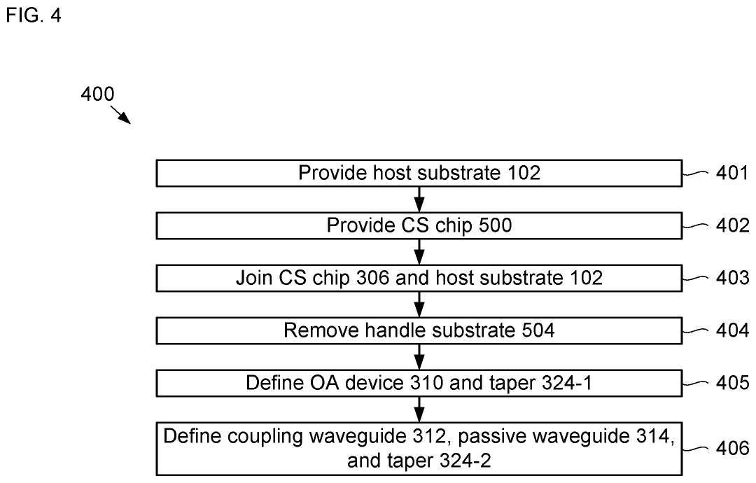

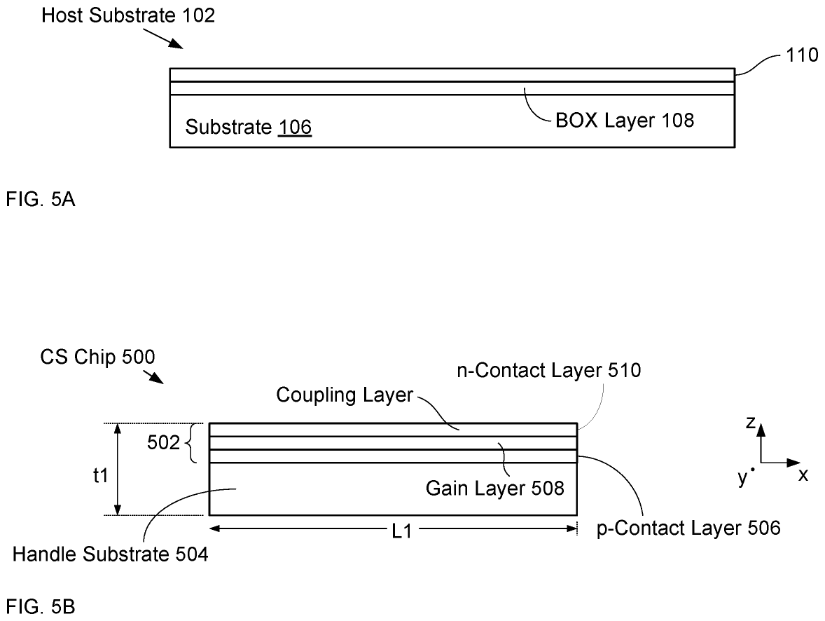

FIG. 4 depicts operations of a method for forming an integrated-optics system in accordance with the present disclosure. Method 400 begins with operation 401, wherein host substrate 102 is provided such that it includes silicon waveguide 316. Method 400 is described with continuing reference to FIG. 3, as well as reference to FIGS. 5A-B and 6A-B.

FIGS. 5A-B depict schematic drawings of cross-sectional views of a host substrate and CS chip, respectively, in accordance with the present disclosure.

As discussed briefly above and with respect to the prior art approach depicted in FIGS. 2A-B, host substrate 102 is a conventional silicon-on-insulator (SOI) wafer comprising handle substrate 106, BOX 108, and device layer 110. In the depicted example, handle substrate 106 is a conventional silicon wafer, BOX 108 is a layer of thermally grown silicon dioxide having a thickness that is typically within the range of approximately 1-2 microns and, preferably, 2 microns, and device layer 110 is a layer of single-crystal silicon having a thickness equal to approximately 220 nm.

It should be noted, however, that handle substrate 106 can be any substrate suitable for use in system 300 without departing from the scope of the present disclosure. Examples of substrates suitable for use in accordance with the present disclosure include, without limitation, glass substrates, compound-semiconductor substrates, bulk silicon substrates, and the like.

Silicon waveguide 316 is a portion of device layer 110 that is has been patterned to define a rib waveguide for supporting single-mode propagation of light signal 318. In some embodiments, silicon waveguide 316 has a waveguide structure other than that of a rib waveguide, such as a channel waveguide, strip waveguide, ridge waveguide, etc. In some embodiments, the waveguide may support multiple optical modes.

In some embodiments, host substrate 102 includes a silicon nitride (SiN) waveguide instead of, or in addition to, silicon waveguide 316.

At operation 402, CS chip 500 is provided.

CS chip 500 includes CS stack 502 disposed on handle substrate 504.

Handle substrate 504 is a conventional germanium substrate suitable for supporting growth of CS stack 502.

As will be appreciated by one skilled in the art, high-quality growth of compound-semiconductor material on germanium substrates has been demonstrated in the prior art. For example, growth of gallium arsenide on germanium substrates with quality comparable to gallium arsenide grown on gallium arsenide substrates has been disclosed by J. Baker, et al., in “Impact of Strain-Induced Bow on the Manufacture of VCSELs on 150 mm GaAs- and Ge-Substrate wafers,” in the Digest of the International Conference on Compound Semiconductor Manufacturing Technology (CSManTech), Monterey, CA (2022) and by A. Johnson, et al., in “First Demonstration Of High Performance 940 nm VCSELs Grown On 200 mm Diameter Substrates”, in the Digest of the International Conference on Compound Semiconductor Manufacturing Technology (CSManTech), Monterey, CA (2022), each of which is incorporated herein by reference.

It is an aspect of the present disclosure that the use of a germanium handle substrate on which compound-semiconductor layers have been grown affords significant advantages to methods for heterogeneous integration of compound-semiconductor material on indirect-semiconductor substrates, as discussed below.

CS stack 502 includes the constituent layers of OA device 310, including contact layers, cladding layers, carrier confinement layers, and a gain layer. In the depicted example, OA device 310 is a quantum-dot laser and CS stack 502 includes p-contact layer 506, gain layer 508, and n-contact layer 510. In some embodiments, OA device 310 is a different optically active device, such as an optical modulator (e.g., an electro-absorption modulator, a phase modulator, etc.), an optical amplifier, a variable optical attenuator, a photodetector, and the like. As will be apparent to one skilled in the art, in some embodiments, CS stack 502 includes other layers in addition to p-contact layer 506, gain layer 508, and n-contact layer 510.

In the depicted example, p-contact layer 506 is a layer of p-doped gallium arsenide suitable for the formation of p-type electrical contacts, gain layer 508 is a layer of gallium arsenide comprising a plurality of quantum dots that enable optical gain within the gain layer, and n-contact layer 510 is a layer of n-doped gallium arsenide suitable for the formation of n-type electrical contacts.

Although the illustrative embodiment includes a gain layer comprising a plurality of quantum dots, gain layer 508 can include any one or more of a wide variety of quantum elements without departing from the scope of the present disclosure. Quantum elements suitable for inclusion in gain layer 508 include, without limitation, quantum wells, quantum-well layers, quantum wires, quantum dashes, and the like.

It should be noted that, in the depicted example, n-contact layer 510 is also configured to function as a coupling layer that can at least partially support the optical mode of the optical energy generated in OA device 310, as well as support the propagation of light signal 318 when properly patterned to define coupling waveguide 312, as discussed below.

In some embodiments, CS chip 500 includes an additional layer disposed on n-contact layer 510, where this additional layer functions as a coupling layer that is suitable for the formation of coupling waveguide 312.

At operation 403, CS chip 500 is joined to host substrate 102.

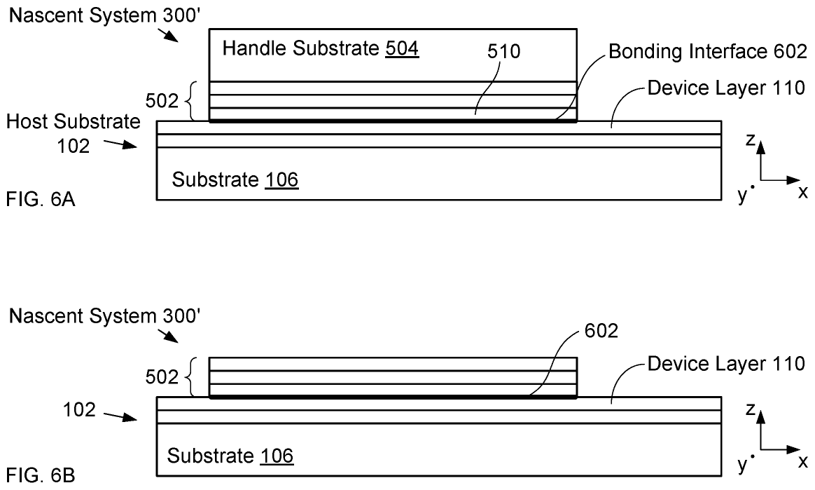

FIG. 6A depicts a schematic drawing of nascent system 300′ after CS chip 500 and host substrate 102 are joined in accordance with the illustrative embodiment.

In the depicted example, CS chip 500 is joined to host substrate 102 via conventional bonding methods such that n-contact layer 510 is bonded with device layer 110 at bonding interface 602. In some embodiments, one or more intervening layers reside between n-contact layer 510 and device layer 110 when CS chip 500 is joined to host substrate 102.

At operation 404, handle substrate 504 is removed.

In sharp contrast to the prior art, it is an aspect of the present disclosure that the use of a germanium substrate for a compound-semiconductor chip to be bonded to a silicon-based substrate significantly simplifies heterogeneous integration. The use of a germanium-handle-substrate-based compound-semiconductor chip affords embodiments in accordance with the present disclosure with significant advantages over the prior art, including:
i. simpler fabrication; or
ii. fewer processing steps; or
iii. less host-material real-estate; or
iv. lower potential cost; or
v. reduced compound-semiconductor material due to utilization of edge portions; or
vi. no need to protect the compound-semiconductor material during removal of the germanium substrate; or
vii. potentially higher yield; or
viii. smoother topography after handle-substrate removal; or
ix. any combination of i, ii, iii, iv, v, vi, vii, and viii.

The ability to reduce or eliminate unusable material near the edge of a CS stack bonded to a host substrate is a significant advantage over the prior art. It is estimated that, in some embodiments, this can reduce the amount of compound semiconductor needed to approximately one-half that required by analogous prior-art systems.

Furthermore, because the topography of heterogeneously integrated material in accordance with the present disclosure is significantly less than in the prior art, the teachings herein enable device manufacture using wafer-scale heterogeneous integration approaches in accordance with more standard techniques used by large-scale foundries, thereby offering higher overall yield via reduced manufacturing variation, as well as improved reliability via the reduction of contaminate/manufacturing defect related failure mechanisms.

Returning now to method 400 and operation 404, since a CS chip handle substrate in accordance with the present disclosure is made of germanium, it can be removed via any of a variety of well-known wet or dry etches that highly selectively etch germanium, while not significantly attacking gallium arsenide or its compounds.

In the depicted example, handle substrate 504 is removed by exposing the germanium to water. In some embodiments, handle substrate 504 is removed by exposing the germanium to a different selective wet etchant, such as hydrogen peroxide, as described by S. Sioncke, et al., in ECS Trans., Vol. 16, No. 451 (2008), and by D. C. DeSalvo, et al., J. Electrochem. Soc., Vol. 139, No. 831 (1992), each of which is incorporated herein by reference.

In some embodiments, handle substrate 504 is removed in a selective dry etch, such as described by Venkatasubramanian, et al., in “Selective plasma etching of Ge substrates for thin freestanding GaAs/AlGaAs heterostructures”, Applied Physics Letters, Vol. 59, 2153 (1991); doi: 10.1063/1.106110, which is incorporated herein by reference.

FIG. 6B depicts a schematic drawing of nascent system 300′ after the removal of handle substrate 504.

At operation 405, p-contact layer 506 and gain layer 508 are patterned to define OA device 310 and taper 324-1.

At operation 406, n-contact layer 510 is patterned to define coupling waveguide 312, passive waveguide 314, and taper 324-2. Taper 324-2 and silicon waveguide 316 collectively define vertical coupler 328-2.

In some embodiments, n-contact layer 510 includes at least two sub-layers that are configured to substantially confine at least a portion of the optical mode of light signal 318 to one of these sub-layers as the light signal propagates through passive waveguide 314.

Tapers 324-1 and 324-2 are configured to enable vertical coupling of the optical mode of light signal 318 from OA device 310 into coupling waveguide 312 and from passive waveguide 314 into silicon waveguide 316.

It should be noted that the waveguide configuration of system 300 is merely exemplary and that myriad alternative arrangements of waveguides can be used to enable propagation of a light signal through a heterogeneously integrated optical system.

Although the illustrative embodiment depicted in FIG. 3 is configured such that optical energy generated in AO Device 310 vertically couples from OE device 310 into passive waveguide 314 and then silicon waveguide 316, in some embodiments, a fully or partially processed laser structure residing on a germanium substrate is edge coupled with a waveguide residing on host substrate 102.

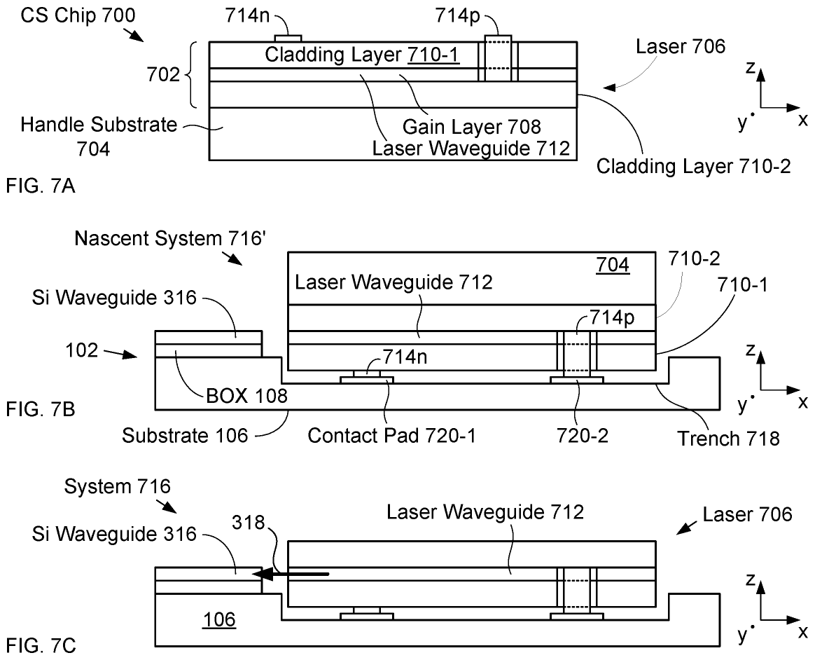

FIG. 7A depicts a schematic drawing of a cross-sectional view of a portion of a compound-semiconductor chip in accordance with an alternative embodiment comprising a laser that is edge coupled with a silicon waveguide in accordance with the present disclosure.

CS chip 700 is analogous to CS chip 500; however, in CS chip 700, CS stack 702 is fully processed while disposed on handle substrate 704 to define laser 706. In some embodiments, CS stack 702 is only partially processed while disposed on handle substrate 704.

CS stack includes gain layer 708, which resides between cladding layers 710-1 and 710-2. In the depicted example, gain layer 708 and cladding layers 710-1 and 710-2 comprise gallium arsenide compounds, where the cladding layers are configured such that the indices of refraction of their material are lower than that of the material of gain layer 708. Gain layer 708 includes a plurality of quantum elements, as discussed above and with respect to gain layer 508. In the depicted example, the quantum elements are quantum dots.

During the formation of CS stack 702, gain layer 708 is patterned to define the lateral dimensions of laser waveguide 712 such that it is configured for high-efficiency edge coupling with silicon waveguide 316.

In addition, n contact 714n and p contact 714p (referred to, collectively, as contacts 714) are configured to enable electrical excitation of laser 706. n contact 714n is disposed on the top surface of CS stack 702 such that it is in electrical contact with cladding layer 710-1, while p contact 714p is formed such that it is in electrical contact with cladding layer 710-2. Typically, p contact 714p resides within a via that extends through cladding layer 710-1 and gain layer 708 as shown; however, any suitable configuration for one or both of contacts 714 can be used without departing from the scope of the present disclosure. As will be appreciated by one skilled in the art, laser contacts (e.g., contacts 714) are normally laterally displaced from one another (along the y direction as shown) and disposed along most, if not all, of the length of laser 706. For clarity and ease of description, however, they are shown in FIGS. 7A-C as being displaced from one another along the x-direction.

FIG. 7B depicts a schematic drawing of a cross-sectional view of a nascent integrated-optics system in accordance with the alternative embodiment. Nascent system 716′ includes CS chip 700, which is oriented top surface down and physically and electrically connected with host substrate 102, as discussed below.

In system 716, handle substrate 106 includes optional trench 718, which is configured to enable good vertical alignment between laser 706 and silicon waveguide 316. In addition, handle substrate 106 includes contact pads 720-1 and 720-2 (referred to, collectively, as contact pads 720), which are configured for providing electrical excitation to laser 706 once system 716 is complete.

As will be apparent to one skilled in the art, after reading this Specification, the depth of trench 718 is based on the thickness of cladding layer 710-1, contact pads 720, and contacts 714. In some embodiments, handle substrate 106 does not include a trench.

CS chip 700 and host substrate 102 are joined using conventional metal-to-metal bonding to electrically and physically join contacts 714 and contact pads 720.

In the prior art, handle substrate 704 is a compound semiconductor (e.g., gallium arsenide) substrate having a thickness that is very large. It is problematic to thin substrate 704 before placing it onto a host wafer, and, as discussed above, thinning it after placement is also challenging, such prior-art systems can have significant challenges with respect to packaging and/or integration with other chips.

It is an aspect of the present disclosure, however, that laser 706 can be joined with host substrate 102 while handle substrate 704 retains its full, or nearly full, thickness, followed by complete removal of the germanium substrate using a relatively simple etch. As a result, damage that commonly occurs during bonding due to the fragile nature of a thinned CS chip is mitigated, thereby improving yield and reducing fabrication cost.

Once CS chip 700 and handle substrate 704 are joined, system 716 is completed by removing handle substrate 704 using a selective germanium etch, as discussed above.

FIG. 7C depicts a schematic drawing of a cross-sectional view of completed system 716.

It should be noted that, in some embodiments, CS chip 700 and host substrate 102 are joined at a bonding interface, such as bonding interface 602, using a conventional bonding method. In such embodiments, contact pads 720 are not included on host substrate 102 and contacts 714 are formed on CS chip 700 after it has been joined to the host substrate.

In some embodiments, protection layers are used to protect other portions of system 716 and/or host substrate 102 during the removal of handle substrate 704; however, it is straightforward to design a system such that only handle substrate 704 is removed and the rest of the system is unaffected.

In some embodiments, multiple compound-semiconductor devices can be formed on a common germanium substrate. After their formation, these devices can be bonded together simultaneously to a host substrate while still attached to the common germanium substrate, thereby enabling simultaneous placement of multiple devices onto predetermined locations on the host wafer. In some such embodiments, two or more of the multiple compound-semiconductor devices are configured to operate as different parts of the same system. After bonding, the Ge substrate can then be removed as described above.

As a result, the teachings of the present disclosure enable easier packaging and integration of optical devices (as well as compound-semiconductor non-optical devices/sub-systems) onto silicon substrates, leaving a more planar surface on the host wafer.

In some embodiments, host substrate 102 includes a silicon nitride (SiN) waveguide instead of, or in addition to, silicon waveguide 316. In some embodiments, a laser (or other optical element) is disposed above silicon waveguide 316 (or SiN waveguide) and light signal 318 is vertically coupled between the optical element and the waveguide via a grating coupler or turning mirror. In some embodiments, an optical element is evanescently coupled with the silicon (or SiN) waveguide.

It is to be understood that the disclosure teaches just some examples of the illustrative embodiment and that many variations of the invention can easily be devised by those skilled in the art after reading this disclosure and that the scope of the present invention is to be determined by the following claims.

What is claimed is:

1. A method including:
providing a compound-semiconductor (CS) chip that includes a first CS layer disposed on a first handle substrate comprising germanium;
providing a host substrate including a first layer that comprises a first material that is selected from the group consisting of a dielectric layer and an indirect-bandgap semiconductor;
joining the CS chip and the host substrate such that the first CS layer is between the host substrate and the first handle substrate; and
removing the first handle substrate.

2. The method of claim 1 wherein the CS chip includes a first CS stack disposed on the first handle substrate, the first CS stack comprising a first plurality of CS layers that includes the first CS layer.

3. The method of claim 2 wherein the first plurality of CS layers includes a gain layer comprising a quantum element.

4. The method of claim 2 wherein the method further includes processing the first CS stack to form a first optically active device that is optically coupled with the first layer.

5. The method of claim 4 wherein the first CS stack is processed to define the first optically active device as a laser.

6. The method of claim 4 wherein the CS chip is provided such that it includes a second CS stack comprising a second plurality of CS layers, and wherein the process further includes processing second CS stack to define a second optically active device that is selected from the group consisting of a laser, an optical amplifier, an electro-absorption modulator, and a phase modulator.

7. The method of claim 4 wherein the CS chip is provided such that it includes a second CS stack comprising a second plurality of CS layers, and wherein the method further includes processing the second CS stack to form a second optically active device that is optically coupled with the first layer.

8. The method of claim 1 wherein the host substrate is provided such that (1) the first layer comprises single-crystal silicon and is disposed on a second handle substrate and (2) the first layer is patterned to define at least one silicon waveguide.

9. The method of claim 8 wherein the CS chip is provided such that the first CS layer comprises a compound semiconductor selected from the group consisting of gallium arsenide, indium phosphide, indium gallium arsenide, aluminum gallium arsenide, and indium gallium arsenide phosphide.

10. The method of claim 1 wherein the host substrate is provided such that (1) the first layer comprises silicon nitride and is disposed on a second handle substrate and (2) the first layer is patterned to define at least one waveguide.

11. The method of claim 1 wherein the host substrate is provided such that the first layer is disposed on a second handle substrate that includes a trench, the first layer being patterned to define a first waveguide, and wherein the CS chip includes a second waveguide, and further wherein the CS chip and the host substrate are joined such that the first and second waveguides are optically coupled.

12. A method including:
providing a compound-semiconductor (CS) chip that includes a plurality of CS layers that collectively define a CS stack, the CS stack being disposed on a first handle substrate consisting of germanium;
providing a host substrate that is a silicon-on-insulator substrate including a silicon handle substrate, a buried oxide layer, and a device layer that comprises single-crystal silicon, wherein the device layer is patterned to define a first silicon waveguide;
joining the CS chip and the host substrate such that the CS stack is between the silicon handle substrate and the first handle substrate; and
removing the first handle substrate.

13. The method of claim 12 wherein the plurality of CS layers includes a gain layer comprising a quantum element.

14. The method of claim 13 wherein the quantum element is a quantum dot.

15. The method of claim 12 further including processing the first CS stack to define a first optically active device that is optically coupled with the first silicon waveguide.

16. The method of claim 15 wherein the first CS stack is processed to define the first optically active device as a laser.

17. The method of claim 15 wherein the CS chip is provided such that it includes a second CS stack comprising a second plurality of CS layers, and wherein the process further includes processing second CS stack to define a second optically active device that is selected from the group consisting of a laser, an optical amplifier, an electro-absorption modulator, and a phase modulator.

18. The method of claim 17 wherein host substrate is provided such that the device layer is patterned to define a second silicon waveguide, and wherein the second CS stack is processed such that the second optically active device is optically coupled with the second silicon waveguide.

19. The method of claim 12 wherein the CS stack and host substrate are joined such that a first layer of the CS stack is joined with the first waveguide at a bonding interface.

20. The method of claim 12 wherein the host substrate is provided such that the silicon-on-insulator substrate includes a trench, and wherein the CS stack includes a second waveguide, and further wherein the CS stack and host substrate are joined such that the CS stack is located in the trench and the first and second waveguides are optically coupled.
